(19) United States
(12) Patent Application Publication
(10) Pub. No.: US 2025/0324649 A1
(43) Pub. Date: Oct. 16, 2025

(54) GATE-ALL-AROUND FIELD EFFECT TRANSISTOR

(71) Applicant: EMEMORY TECHNOLOGY INC., HSINCHU (TW)

(72) Inventors: LUN-CHUN CHEN, HSINCHU COUNTY (TW); PING-LUNG HO, HSINCHU COUNTY (TW)

(21) Appl. No.: 19/091,818

(22) Filed: Mar. 27, 2025

Related U.S. Application Data
(60) Provisional application No. 63/632,599, filed on Apr. 11, 2024.

(51) Int. Cl. H10D 30/00; H10D 62/10

(52) U.S. Cl. CPC H10D 30/503; H10D 62/121

(57) ABSTRACT

A gate-all-around field effect transistor (GAAFET) includes a substrate, a source structure, a drain structure, at least one channel, and a gate structure. The source structure and the drain structure are disposed on the substrate. Each of the at least one channel is extending between the source structure and the drain structure. The gate structure is disposed between the source structure and the drain structure, and surrounding the at least one channel. When the GAAFET is operated in a saturation state, each of the at least one channel comprises a first region, a second region, and an electrical junction between the first region and the second region. The first region is adjacent to the drain structure, and the second region is adjacent to the first region.

### CROSS REFERENCE

This application claims the benefit of prior-filed U.S. provisional application No. 63/632,599, filed on Apr. 11, 2024, which is incorporated by reference in its entirety.

### TECHNICAL FIELD

The present disclosure relates to a gate-all-around field effect transistor (GAAFET), and more particularly, to a GAAFET of high reliability.

### DISCUSSION OF THE BACKGROUND

The gate-all-around field-effect transistor (GAAFET) is a type of transistor that has been developed as a potential replacement for FinFET transistors in semiconductor technology. The GAAFET, as its name suggests, has its gate surrounding the channels on all sides, allowing for a larger contact area between the gate and the channel, thereby enhancing the control of the gate over the current.

Although the GAAFET has been considered as an advanced FET that provides better performance in a smaller footprint, the GAAFET also faces some challenges as the technology keeps scaling down. For example, the GAAFET may suffer from the short-channel-effects due to the decreased length of the channels. Also, the junction breakdown voltage of the GAAFET can be rather low, making it difficult to be adopted for high voltage application, such as the One-time-Programing (OTP) memory application which requires high voltage operation for program operations. Therefore, how to develop a more reliable GAAFET that can be applied to a wider range of fields has become an issue to be solved.

The background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a gate-all-around field effect transistor (GAAFET). The GAAFET includes a substrate, a source structure, a drain structure, at least one channel, and a gate structure. The source structure is disposed on the substrate, and the drain structure is disposed on the substrate. Each of the at least one channel extends between the source structure and the drain structure. The gate structure is disposed between the source structure and the drain structure, and surrounds the at least one channel. When the GAAFET is operated in a saturation state, each of the at least one channel includes a first region, a second region, and an electrical junction between the first region and the second region. The first region is adjacent to the drain structure, and the second region is adjacent to the first region.

Since the channel of the GAAFET has regions of different equivalent carrier densities, additional junctions can be induced within the channel, thereby improving the reliability of the GAAFET in terms of resisting the short channel effects. Also, the induced junctions can also help to weaken the electric fields formed at the drain, and thus can help to increase the breakdown voltage of the GAAFET.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a gate-all-around field effect transistor (GAAFET) according to one comparative embodiment of the present disclosure.

FIG. 2 shows the charge distribution among the source structure, the drain structure, and the channel of the GAAFET in FIG. 1.

FIG. 3 shows a GAAFET according to one embodiment of the present disclosure.

FIG. 4 shows a perspective view of the channel of the GAAFET in FIG. 3 according to one embodiment of the present disclosure.

FIG. 5 shows band diagrams of different regions of the channel of the GAAFET in FIG. 3 according to one embodiment of the present disclosure.

FIG. 6 shows the charge distribution among the source structure, the drain structure, and the channel of the GAAFET in FIG. 3 according to one embodiment of the present disclosure.

FIG. 7 shows a GAAFET according to another embodiment of the present disclosure.

FIG. 8 shows the charge distribution among the source structure, the drain structure, and the channel of the GAAFET in FIG. 7 according to one embodiment of the present disclosure.

FIG. 9 shows a channel according to one embodiment of the present disclosure.

FIG. 10 further shows a channel according to another embodiment of the present disclosure.

FIG. 11 shows a channel according to another embodiment of the present disclosure.

FIG. 12 shows a channel according to another embodiment of the present disclosure.

FIG. 13 shows a channel according to another embodiment of the present disclosure.

FIG. 14 shows a GAAFET according to another embodiment of the present disclosure.

FIG. 15 shows a GAAFET according to another embodiment of the present disclosure.

### DETAILED DESCRIPTION

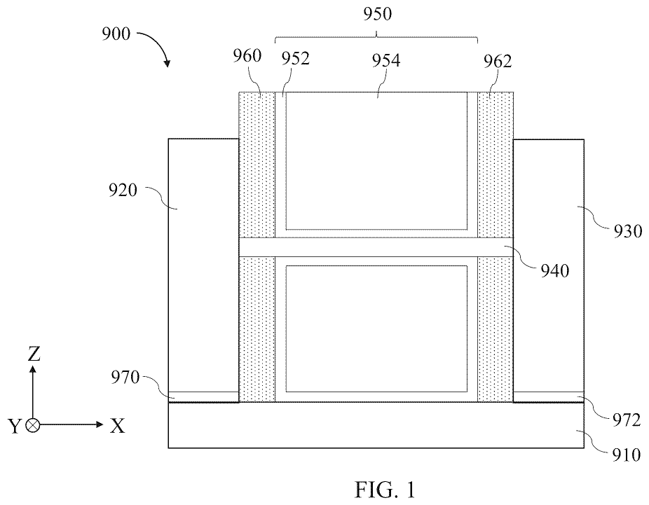

FIG. 1 shows a gate-all-around field effect transistor (GAAFET) 900 according to one comparative embodiment of the present disclosure. In FIG. 1, the GAAFET 900 includes a substrate 910, a source structure 920, a drain structure 930, a channel 940, a gate structure 950, spacers 960 and 962, and dielectric layers 970 and 972. The GAAFET 900 can be an N-Channel metal-oxide silicon (NMOS) transistor. In such case, the source structure 920 and the drain structure 930 are doped with N-type carriers, and the channel 940 is lightly doped with P-type carriers. The gate structure 950 includes dielectric layers 952 and gate layers 954 surrounded by the dielectric layers 952.

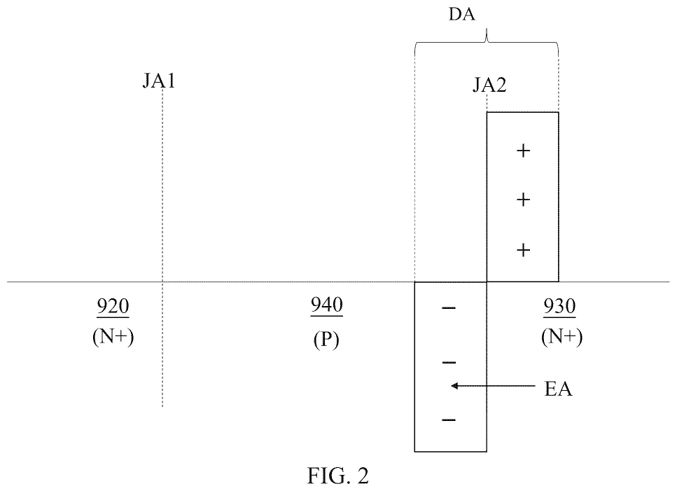

FIG. 2 shows the charge distribution among the source structure 920, the drain structure 930, and the channel 940 when the GAAFET 900 is operated in the saturation state. As shown in FIG. 2, since a positive voltage is applied to the drain structure, the drain structure 930 and the channel 940 are reversely biased, thereby forming a depletion region DA near the junction JA2. Near the source structure 920, the channel 940 is in the inverse mode and therefore has no depletion region near the junction JA1. Since the channel length of the GAAFET 900 is rather short, when a high positive voltage is applied to the drain structure 930, the depletion region DA may expand to the source structure. Under this circumstance, the short channel effects, such as the drain induced barrier lowering (DIBL) or channel punch through, can be induced. In other words, the GAAFET 900 faces challenges of short channel effects.

In addition, an electric field EA is formed at the junction JA2 by the immobile donors and acceptors as shown in FIG. 2. In such case, when the drain structure 930 receives a high voltage and the source structure 920 receives a low voltage (e.g., 0 V), the electric field EA at the junction JA2 will be further enhanced, and the strong electric field EA may damage the GAAFET 900. In other words, the low breakdown voltage hinders the use of the GAAFET 900 as a one-time programmable (OTP) memory cell which is usually programmed by large voltage difference.

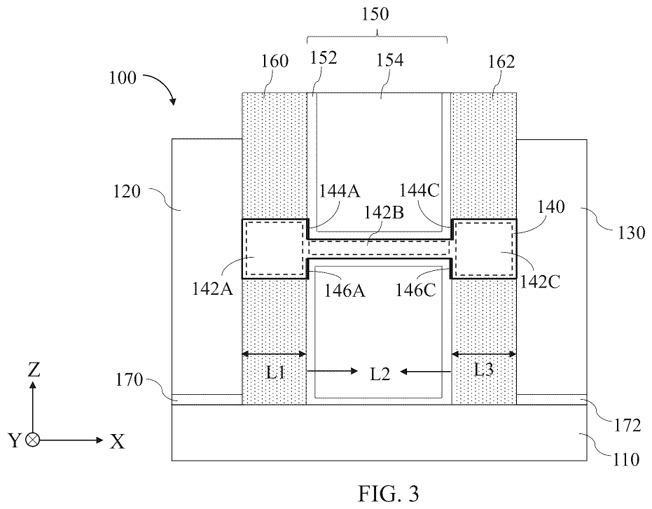

FIG. 3 shows a GAAFET 100 according to one embodiment of the present disclosure. Comparing to the GAAFET 900, the GAAFET 100 can have a higher breakdown voltage and better immunity against the short-channel-effects.

The GAAFET 100 includes a substrate 110, a source structure 120, a drain structure 130, a channel 140, a gate structure 150, spacers 160 and 162, and dielectric layers 170 and 172. The source structure 120 and the drain structure 130 are disposed on the substrate 110 with the dielectric layer 170 being disposed between the source structure 120 and the substrate 110 and the dielectric layer 172 being disposed between the drain structure 130 and the substrate 110.

The gate structure 150 includes dielectric layers 152 and gate layers 154 surrounded by the dielectric layers 152. The dielectric layers 152 may include silicon oxide, silicon nitride or high-K dielectric material. The gate layer 154 may include polysilicon or a metal gate electrode. The gate structure 150 is disposed between the source structure 120 and the drain structure 130, the spacer 160 is disposed between the gate structure 150 and the source structure 120, and the spacer 162 is disposed between the gate structure 150 and the drain structure 130. The channel 140 extends between the source structure 120 and the drain structure 130 with the gate structure 150 surrounding the channel 140. That is, as shown in FIG. 3, the channel 140 can pass through the gate structure 150 and contact the source structure 120 and the drain structure 130 with its two ends.

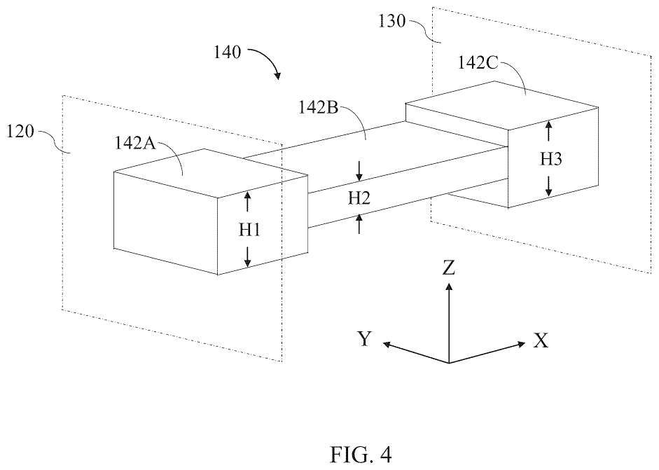

In some embodiments, the channel 140 can be formed by a nanowire, such as a rectangular nanowire or a cylindrical nanowire. Furthermore, the channel 140 can include a region 142A, a region 142B, and a region 142C. The region 142A is adjacent to the source structure 120, the region 142C is adjacent to the drain structure 130, and the region 142B is disposed between the region 142A and the region 142C. FIG. 4 shows a perspective view of the channel 140 according to one embodiment of the present disclosure.

As shown in FIG. 4, a height H1 of the region 142A and a height H3 of the region 142C are greater than a height H2 of the region 142B, where the heights H1, H2, and H3 are measured along the stacking direction Z of the gate structure 150 and the channel 140. Furthermore, in the present embodiment, the regions 142A and 142C are surrounded by the spacers 160 and 162 while the region 142B is surrounded by the dielectric layer 152 as shown in FIG. 3.

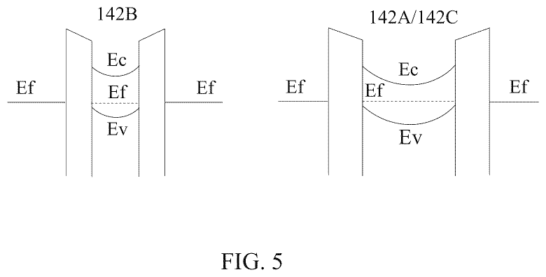

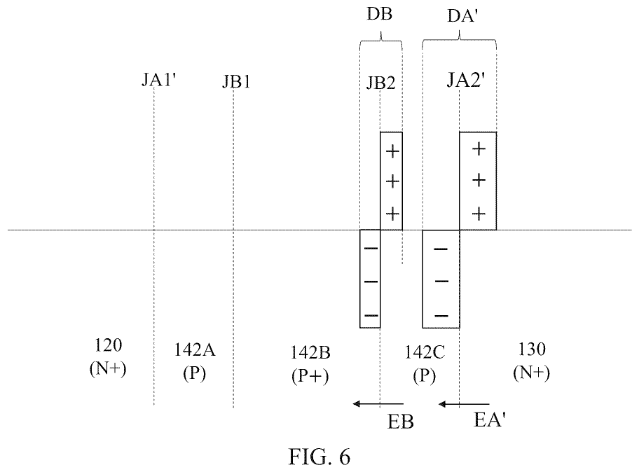

FIG. 5 shows the band diagrams of regions 142A/142C and 142B of the channel 140 according to one embodiment of the present disclosure. Generally, the Fermi level of the channel 140 can be lowered by the gate structure 150, (e.g., the gate layer 154), and thus the band of the channel 140 is bent. In specific, around the surface of the channel 140, the top of valence band (hereinafter referred to as “the level Ev”) is raised to be close to the fermi level Ef, and the bottom of the conduction band (hereinafter referred to as “the level Ec”) is raised to be away from the fermi level. In such case, as shown in FIG. 5, the region 142A and the region 142C, comparing to the region 142B, are less affected by the gate structure 150 due to the greater heights and the covering of spacers 160 and 162. Therefore, the levels Ev and Ec of the region 142B are, on average, higher than the levels Ev and Ec of the regions 142A and 142C. Consequently, although the three regions 142A, 142B, and 142C are originally doped with the same concentration of carriers (or not doped) when the channel 140 is formed, an equivalent carrier density of the region 142B would be higher than an equivalent carrier density of the region 142A and an equivalent carrier density of the region 142C. For example, if the channel 140 is originally doped with a P-type concentration of P−, the equivalent carrier concentration of the regions 142A and 142C may become P while the equivalent carrier concentration of the region 142B may become P+ as shown in FIG. 6.

FIG. 6 shows the charge distribution among the source structure 120, the drain structure 130, and the channel 140 when the GAAFET 100 is operated in the saturated state. As shown in FIG. 6, since the region 142A and the region 142B have different equivalent carrier densities, an electrical junction (or an induced junction) JB1 can be induced at the interface between the region 142A and the region 142B. Similarly, an electrical junction JB2 can be formed at the interface between the region 142B and the region 142C. In other words, the GAAFET 100 may have four junctions along the path from the drain structure 130 to the source structure 120: the junction JA2′ between the drain structure 130 and the channel 140, the junction JB2 between the region 142C and the region 142B, the junction JB1 between the region 142B and the region 142A, and the junction JA1′ between the channel 140 and the source structure 120. In some embodiments, the height H1 of the region 142A and the height H3 of the region 142C can be more than twice the height H2 of the region 142B, so that observable junctions JB1 and JB2 can be formed in the channel 140. However, the present disclosure is not limited thereto.

In such case, when the GAAFET 100 is operated in the saturation state, as the mobile charges are diffused away from the junction JA2 in the GAAFET 900 to form the depletion regions DA as shown in FIG. 2, the charges can be diffused away from the two junctions JA2′ and JB2 to form the depletion regions DA′ and DB in the GAAFET 100. Therefore, the depletion region DA′ at the junction JA2′ shown in FIG. 6 would be smaller than the depletion region DA at the junction JA2 shown in FIG. 2.

Furthermore, comparing to the electric field EA formed at the junction JA2 in the GAAFET 900 show in FIG. 2, the electric field EA′ formed at the junctions JA2′ in the GAAFET 100 is weakened because of a new electric field EB formed at the additional junction JB2. In other words, the two junctions JA2′ and JB2 collaboratively absorb the drain-to-source bias; therefore, the GAAFET 100 is able to withstand a higher breakdown voltage.

Since the channel 140 of the GAAFET 100 can include different regions that have different equivalent carrier densities, the additional junction JB2 in proximal to the drain structure 130 can be formed in the channel 140, so that the additional electric field EB in proximal to the drain structure 130 is formed, thereby improving the reliability of the GAAFET 100 in terms of resisting the short channel effects. Also, the additional junction JB2 can also help to weaken the electric fields formed at the junction JA2′, and thus can help to increase the breakdown voltage of the GAAFET 100.

As shown in FIG. 3, the regions 142A, 142B, and 142C may have lengths L1, L2, and L3 respectively measured along the extending direction X of the channel 140. In some embodiments, the length L2 may be greater than the lengths L1 and L3. Also, in some embodiments, the lengths L1 and L3 of the regions 142A and 142C can be adjusted according to the needs. For example, by increasing the lengths L1 and L3 of the regions 142A and 142C, the breakdown voltage of the GAAFET 100 may be increased; however, the turn-on resistance of the GAAFET 100 may also be increased.

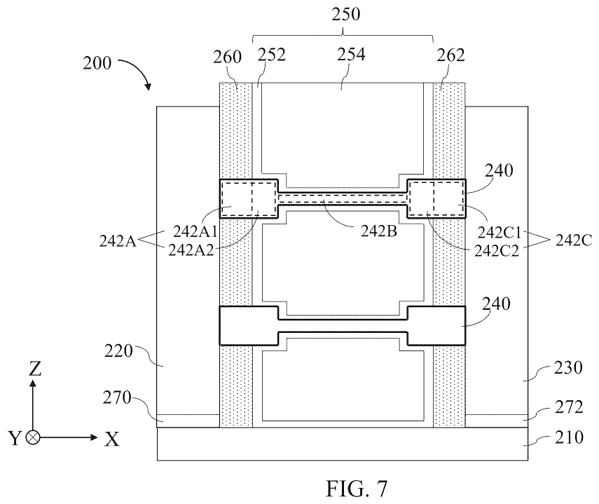

FIG. 7 shows a GAAFET 200 according to another embodiment of the present disclosure. The GAAFET 200 includes a substrate 210, a source structure 220, a drain structure 230, channels 240, a gate structure 250, spacers 260 and 262, and dielectric layers 270 and 272. The gate structure 250 includes the dielectric layer 252 and the gate layer 254. The GAAFET 200 is different from the GAAFET 100 in that the GAAFET 200 includes a plurality of channels 240. Furthermore, it may be noted that in FIG. 3, the region 142A of the channel 140 is surrounded by the spacer 160, and the region 142C of the channel 140 is surrounded by the spacer 162. Also, the region 142B of the channel 140 is surrounded by the dielectric layer 152. However, in FIG. 7, although the channel 240 also includes regions 242A, 242B, 242C (with the heights of the regions 242A and 242C being greater than the height of the region 242B), only parts of the regions 242A and regions 242C are surrounded by the spacer 260 and 262.

Specifically, the region 242A includes two parts 242A1 and 242A2. The part 242A1 is in proximal to the source structure 220 while the part 242A2 is in distal from the source structure 220. In such case, the part 242A1 is surrounded by the spacer 260, and the part 242A2 is surrounded by the dielectric layer 252 of the gate structure 250. Therefore, comparing to the part 242A2, the part 242A1 surrounded by the spacer 260 is less affected by the gate structure 250, and thus, the equivalent carrier density (e.g. P−) of the part 242A1 will be lower than the equivalent carrier density (e.g. P) of the part 242A2. In some embodiments, in view along a direction Y perpendicular to the direction X and the direction Z, a cross section of the gate layer 254 between two channels 240 may form a cross shape.

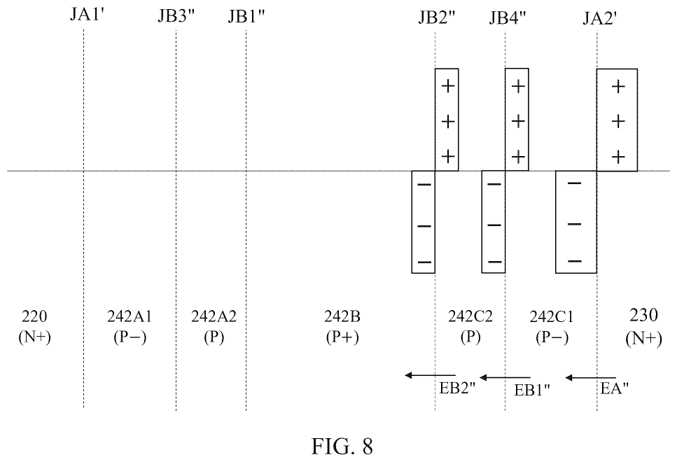

FIG. 8 shows the charge distribution among the source structure 220, the drain structure 230, and the channel 240 when the GAAFET 200 is operated in the saturation state. As shown in FIG. 8, an electrical junction JB3″ can be induced between the two parts 242A1 and 242A2 due to the different equivalent carrier densities.

Similarly, the region 242C includes two parts 242C1 and 242C2. The part 242C1 is in proximal to the drain structure 230 while the part 242C2 is in distal from the drain structure 230. Also, the part 242C1 is surrounded by the spacer 262, and the part 242C2 is surrounded by the dielectric layer 252 of the gate structure 250. Therefore, the equivalent carrier density of part 242C1 (e.g. P−) will be lower than the equivalent carrier density of the part 242C2 (e.g. P). As a result, an electrical junction JB4″ can be induced between the two parts 242C1 and 242C2.

That is, in the present embodiment, four junctions JB1″, JB2″, JB3″, and JB4″ can be induced within the channel 240. Specifically, the junction JB3″ is induced between the parts 242A1 and 242A2 of the region 242A, the junction JB1″ is induced between the regions 242A and 242B, the junction JB2″ is induced between the regions 242B and 242C, and the junction JB4″ is induced between the parts 242C2 and 242C1 of the region 242C. In some embodiments, the junction JB3″ and the junction JB1″ may be very close, and they may be merged into one greater junction. Similarly, the junction JB2″ and the junction JB4″ may be merged into one greater junction. As a result, when the GAAFET 200 is operated in the saturation state, the electric field applied to the drain structure 230 can be alleviated since the electric field is distributed to the induced junctions JA2′, JB4″, and JB2″ as electric fields EA″, EB1″ and EB2″, and, therefore, the breakdown voltage of the GAAFET 200 can be increased. Also, the reliability of the GAAFET 200 in terms of resisting the short channel effects can also be improved as the depletion regions are distributed to more junctions and decrease in size.

Referring to FIG. 3. In the GAAFET 100, the region 142A includes sidewalls 144A and 146A that are perpendicular to the extending direction X of the channel 140, where the sidewall 144A is connected to an upper surface of the region 142B that is distal from the substrate 110, and the sidewall 146A is connected to a lower surface of the region 142B that is proximal to the substrate 110. Similarly, the region 142C includes sidewalls 144C and 146C that are perpendicular to the extending direction X of the channel 140, where the sidewall 144C is connected to the upper surface of the region 142B that is distal from the substrate 110, and the sidewall 146C is connected to the lower surface of the region 142B that is proximal to the substrate 110. However, the present disclosure is not limited thereto. In some embodiments, the sidewalls 144A, 146A, 144C, and 146C may not be perpendicular to the extending direction X of the channel 140.

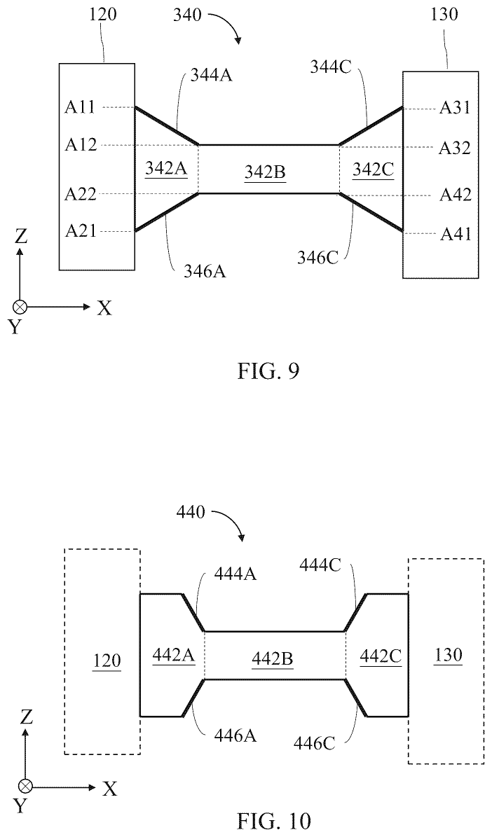

FIG. 9 shows a channel 340 according to one embodiment of the present disclosure. As shown in FIG. 9, the channel 340 includes regions 342A, 342B, and 342C. The region 342A is coupled to the source structure 120, the region 342C is coupled to the drain structure 130, and the region 342B is disposed between the regions 342A and 342C. In the present embodiment, the region 342A includes sidewalls 344A and 346A ramping from a side of the region 342A that is in proximal to the region 342B to another side of the region 342A that is in proximal to the source structure 120. Therefore, the altitude A11 of the sidewall 344A at the side proximal to the source structure 120 is higher than the altitude A12 of the sidewall 344A at the side proximal to the region 342B, and the altitude A21 of the sidewall 346A at the side proximal to the source structure 120 is lower than the altitude A22 of the sidewall 346A at the side proximal to the region 342B.

Similarly, the region 342C includes sidewalls 344C and 346C ramping from a side of the region 342C that is in proximal to the region 342B to another side of the region 342C that is in proximal to the drain structure 130. Therefore, the altitude A31 of the sidewalls 344C at the side proximal to the drain structure 130 is higher than the altitude A32 of the sidewalls 344C at the side proximal to the region 342B, and the altitude A41 of the sidewall 346C at the side proximal to the drain structure 130 is lower than the altitude A42 of the sidewall 346C at the side proximal to the region 342B. In the present embodiment, the altitudes A11, A12, A21, A22, A31, A32, A41, and A42 can be measured along the direction Z.

FIG. 10 further shows a channel 440 according to another embodiment of the present disclosure. The channel 440 includes regions 442A, 442B, and 442C, the region 442A includes sidewalls 444A and 446A, and the region 442C includes sidewalls 444C and 446C. The channel 440 is different from the channel 340 in that the sidewalls 444A and 446A, 444C, and 446C are steeper than the sidewalls 344A and 346A, 344C, and 446C. Therefore, the region 442A further includes flat surfaces that are parallel to the direction X and connect the sidewalls 444A and 446A to the source structure 120. Also, the region 442C further includes flat surfaces that are parallel to the direction X and connect the sidewalls 444C and 446C to the drain structure 130.

In some embodiments, in view along a direction Y perpendicular to the direction X and the direction Z, a cross section of the channel 140, 240, 340 or 440 may form a dumbbell shape as shown in FIGS. 3, 7, 9, and 10.

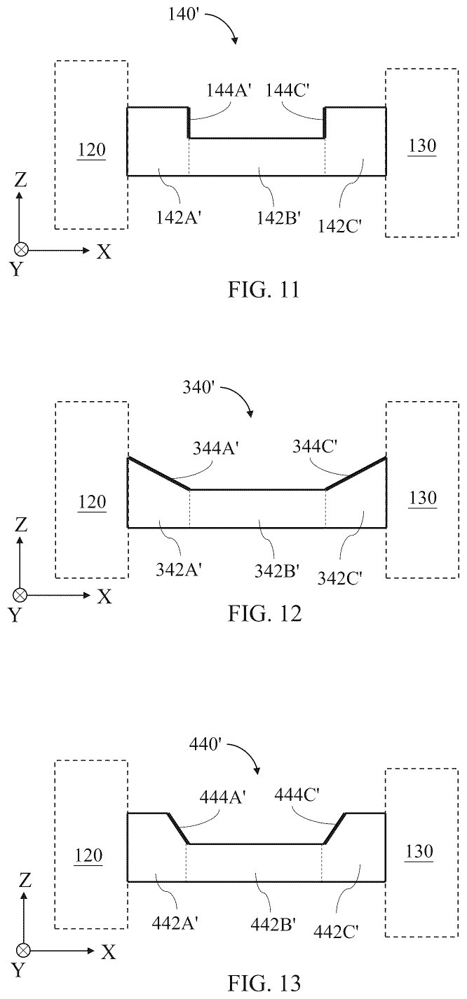

Furthermore, in some embodiments, the region 142A of the channel 140 may include only one sidewall that connects to the upper surface or the lower surface of the region 142B, and the height difference between the region 142A and 142B can still be created. FIG. 11 shows a channel 140′ according to another embodiment of the present disclosure. The channel 140′ is different from the channel 140 in that the region 142A′ includes one sidewall 144A′ connecting to the upper surface of the region 142B′ and the region 142C′ includes one sidewall 144C′ connecting to the upper surface of the region 142B′.

FIG. 12 shows a channel 340′ according to another embodiment of the present disclosure. The channel 340′ is different from the channel 340 in that the region 342A′ includes one sidewall 344A′ connecting to the upper surface of the region 342B′ and the region 342C′ includes one sidewall 344C′ connecting to the upper surface of the region 342B′.

FIG. 13 shows a channel 440′ according to another embodiment of the present disclosure. The channel 440′ is different from the channel 440 in that the region 442A′ includes one sidewall 444A′ connecting to the upper surface of the region 442B′ and the region 442C′ includes one sidewall 444C′ connecting to the upper surface of the region 442B′.

In some embodiments, in view along a direction Y perpendicular to the direction X and the direction Z, a cross section of the channel 140′, 340′ or 440′ may form a U-shape as shown in FIGS. 11, 12, and 13.

In some embodiments, on the direction X, each of the channels in FIGS. 9-13 may have the two outer regions (e.g., the regions 342A and 342C in FIG. 9) surrounded by the spacer, similar as the descriptions with reference to FIG. 3. In some embodiments, on the direction X, each of the channels in FIGS. 9-13 may have the two outer regions (e.g., the regions 342A and 342C in FIG. 9) partially surrounded by the spacer and partially surrounded by the dielectric layer, similar as the descriptions with reference to FIG. 7. In addition, although the channel may have regions having different equivalent carrier densities by forming the different regions of channel with different heights as described, regions having different equivalent carrier densities in the channel may also be created by surrounding different regions of the channel with dielectric layers of different thickness.

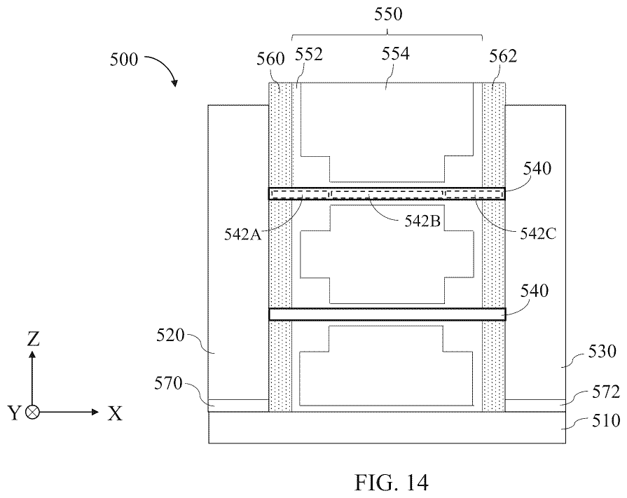

FIG. 14 shows a GAAFET 500 according to one embodiment of the present disclosure. The GAAFET 500 includes a substrate 510, a source structure 520, a drain structure 530, channels 540, a gate structure 550, spacers 560 and 562, and dielectric layers 570 and 572. The gate structure 550 includes the dielectric layer 552 and the gate layer 554. The GAAFET 500 is different from the GAAFET 200 in that a thickness of the dielectric layer 552 stacked on the regions 542A and 542C of each of the channels 540 is greater than a thickness of the dielectric layer 552 stacked on the region 542B of each of the channels 540.

In the present embodiment, since the dielectric layer 552 becomes thicker near the regions 542A and 542C, the regions 542A and 542C would be, comparing to the region 542B, less affected by the gate structure 550. Therefore, although the regions 542A, 542B, and 542C may have the same heights, the equivalent carrier density of the region 542B would still be higher than the equivalent carrier densities of the regions 542A and 542C. As a result, an electronic junction between the region 542A and 542B and an electronic junction between the region 542B and 542C will be induced, thereby increasing the breakdown voltage of the GAAFET 500 and protecting the GAAFET 500 from suffering the short channel effects. In some embodiments, in view along a direction Y perpendicular to the direction X and the direction Z, a cross section of the gate layer 554 between two channels 540 may form a cross shape.

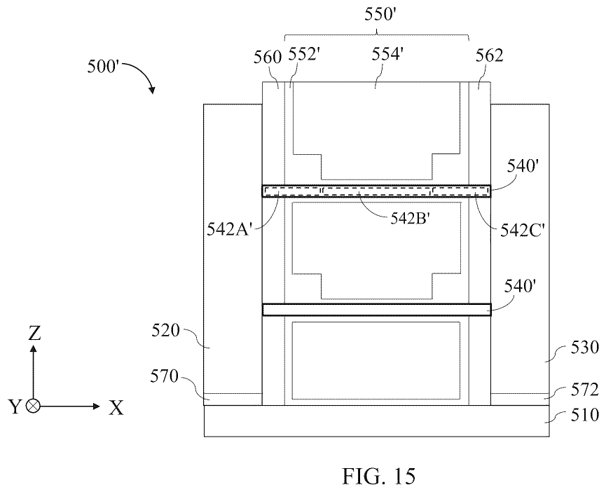

In the GAAFET 500, the dielectric layer 552 can be thicker both above and under the regions 542A and 542C; however, the present disclosure is not limited thereto. FIG. 15 shows a GAAFET 500′ according to one embodiment of the present disclosure. The GAAFET 500′ includes a substrate 510, a source structure 520, a drain structure 530, channels 540′, a gate structure 550′, spacers 560 and 562, and dielectric layers 570 and 572. The gate structure 550′ includes the dielectric layer 552′ and the gate layer 554′. The GAAFET 500′ is different from the GAAFET 500 in that the dielectric layer 552′ is thicker only above the regions 542A′ and 542C′, and the dielectric layer 552′ has the same thickness under the regions 542A′, 542B′, and 542C′. In some embodiments, in view along a direction Y perpendicular to the direction X and the direction Z, a cross section of the gate layer 554′ between two channels 540′ may protrude toward the substrate.

Furthermore, in the previous embodiments, each of the channels 140, 240, 340, 440, 540, 140′, 340′, 440′, and 540′ may include three regions, however, the present disclosure is not limited thereto. In some embodiments, one of the regions that has the lower equivalent carrier density may be omitted. For example, in most of the applications for an NMOS transistor, the short channel effects (e.g., the DIBL) are induced at the drain side since the voltage received by the drain is usually higher than the voltage received by the source. Therefore, the region having the lower equivalent carrier density and being close to the source structure may be omitted, and the region having the lower equivalent carrier density and being close to the drain structure can be preserved so as to preserve the protection for the drain structure.

For example, in some embodiments, the region 142A in the channel 140 can be omitted, and the region 142B can be extended to be coupled to the source structure 120. In such case, the junction JB1 shown in FIG. 6 will not be induced. However, since the region 142C of the channel 140 is preserved, the junction JB2 between the region 142B and 142C can still be induced to protect the drain structure 130 and avoid the short channel effects. Similarly, each of the channels 240, 340, 440, 540, 140′, 340′, 440′, and 540′ may omit the region 242A, 342A, 442A, 542A, 142A′, 342A′, 442A′, or 542A′, and preserve the region 242C, 342C, 442C, 542C, 142C′, 342C′, 442C′, or 542C′.

In summary, the GAAFETs provided by the embodiments of the preset disclosure allows the channel to have regions of different equivalent carrier densities so as to induce additional junctions within the channel, thereby improving the reliability of the GAAFET in terms of resisting the short channel effects. Also, the induced junctions can also help to weaken the electric field formed at the drain, and thus can help to increase the breakdown voltage of the GAAFET.

What is claimed is:

1. A gate-all-around field effect transistor (GAAFET) comprising:
a substrate;
a source structure disposed on the substrate;
a drain structure disposed on the substrate;
at least one channel, each extending between the source structure and the drain structure; and
a gate structure disposed between the source structure and the drain structure, and surrounding the at least one channel,
wherein:
when the GAAFET is operated in a saturation state, each of the at least one channel comprises a first region, a second region, and a first electrical junction between the first region and the second region, and
the first region is adjacent to the drain structure, and the second region is adjacent to the first region.

2. The GAAFET of claim 1, wherein an equivalent carrier density of the second region is higher than an equivalent carrier density of the first region.

3. The GAAFET of claim 1, wherein a height of the first region is greater than a height of the second region, and the height of the first region and the height of the second region are measured along a stacking direction of the at least one channel and the gate structure.

4. The GAAFET of claim 3, wherein the height of the first region is more than twice the height of the second region.

5. The GAAFET of claim 3, wherein:
a first side of the first region is in proximal to the drain structure, a second side of the first region is in proximal to the second region,
the first region comprises a first sidewall ramps from the second side to the first side, and
a first altitude of the first sidewall at the first side is higher than a second altitude of the first sidewall at the second side.

6. The GAAFET of claim 5, wherein:
the first region further comprises a second sidewall ramping from the second side to the first side,
the first sidewall is connected to an upper surface of the second region that is distal from the substrate, and the second sidewall is connected to a lower surface of the second region that is proximal to the substrate, and
a first altitude of the second sidewall at the first side is lower than a second altitude of the second sidewall at the second side.

7. The GAAFET of claim 3, wherein the first region comprises a first sidewall perpendicular to an extending direction of the at least one channel.

8. The GAAFET of claim 7, wherein:
the first region further comprises a second sidewall perpendicular to the extending direction of the at least one channel, and
the first sidewall is connected to an upper surface of the second region that is distal from the substrate, and the second sidewall is connected to a lower surface of the second region that is proximal to the substrate.

9. The GAAFET of claim 1, further comprising a spacer disposed between the drain structure and the gate structure, wherein a first part of the first region is surrounded by the spacer.

10. The GAAFET of claim 9, wherein a second part of the first region is surrounded by a dielectric layer of the gate structure.

11. The GAAFET of claim 10, wherein each of the at least one channel further comprises a second electrical junction between the first part of the first region and the second part of the first region.

12. The GAAFET of claim 1, wherein:
each of the at least one channel further comprises a third region, the third region is adjacent to the source structure,
the second region is disposed between the first region and the third region, and
an equivalent carrier density of the second region is higher than an equivalent carrier density of the third region.

13. The GAAFET of claim 12, further comprising:
a first spacer disposed between the drain structure and the gate structure; and
a second spacer disposed between the source structure and the gate structure,
wherein a first part of the first region is surrounded by the first spacer, and a first part of the third region is surrounded by the second spacer.

14. The GAAFET of claim 13, wherein a second part of the first region and a second part of the third region are surrounded by a dielectric layer of the gate structure.

15. The GAAFET of claim 1, wherein the gate structure comprises a dielectric layer surrounding the at least one channel, and a thickness of the dielectric layer stacked on the first region of each of the at least one channel is greater than a thickness of the dielectric layer stacked on second region of each of the at least one channel.

16. The GAAFET of claim 15, wherein a thickness of the dielectric layer under the first region of each of the at least one channel is greater than a thickness of the dielectric layer under the second region of each of the at least one channel.

17. The GAAFET of claim 1, wherein the at least one channel and the gate structure are stacked along a first direction, and the at least one channel extends along a second direction perpendicular to the first direction,
wherein:
the gate structure comprises a gate layer and a gate dielectric layer, and
in view along a third direction perpendicular to the first direction and the second direction, a cross section of the gate layer forms a cross shape.

18. The GAAFET of claim 1, wherein the at least one channel and the gate structure are stacked along a first direction, and the at least one channel extends along a second direction perpendicular to the first direction,
wherein:
the gate structure comprises a gate layer and a gate dielectric layer, and
in view along a third direction perpendicular to the first direction and the second direction, a cross section of the gate layer protrudes toward the substrate.

19. The GAAFET of claim 1, wherein the at least one channel and the gate structure are stacked along a first direction, and the at least one channel extends along a second direction perpendicular to the first direction,
wherein:
in view along a third direction perpendicular to the first direction and the second direction, a cross section of the at least one channel forms a dumbbell shape.

20. The GAAFET of claim 1, wherein the at least one channel and the gate structure are stacked along a first direction, and the at least one channel extends along a second direction perpendicular to the first direction,
in view along a third direction perpendicular to the first direction and the second direction, a cross section of the at least one channel forms a U-shape.
